(19) United States
(12) Patent Application Publication
(10) Pub. No.: US 2008/0296616 A1
(43) Pub. Date: Dec. 4, 2008

(54) Gallium nitride-on-silicon nanoscale patterned interface

(75) Inventors: Tingkai Li, Vancouver, WA (US); Douglas J. Tweet, Camas, WA (US); Jer-Shen Maa, Vancouver, WA (US); Sheng Teng Hsu, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/809,958

(22) Filed: Jun. 4, 2007

(51) Int. Cl. H01L 21/20; H01L 29/20

(52) U.S. Cl. 257/190; 438/483; 257/E21.09; 257/E29.089

(57) ABSTRACT

A method is provided for forming a matching thermal expansion interface between silicon (Si) and gallium nitride (GaN) films. The method provides a (111) Si substrate that is heated to a temperature in a range of about 300 to 800° C., and a first film is formed in compression overlying the Si substrate. The first film material may be InP, SiGe, GaP, GaAs, AlN, AlGaN, an AlN/graded AlGaN (Al₁₋ₓGaₓN (0<x<1)) stack, or a AlN/graded AlGaN/GaN stack. The first film is then nanoscale patterned and a lateral nanoheteroepitaxy overgrowth (LNEO) process is used to grow a first GaN layer. The above-mentioned processes are repeated, forming a second film in compression that is nanoscale patterned, and a second GaN layer is grown using the LNEO process. The first and second GaN layers are formed by heating the Si substrate to a temperature in a range of 1000 to 1200° C.

### BACKGROUND OF THE INVENTION

1. Field of the Invention

This invention generally relates to integrated circuit (IC) fabrication and, more particularly to a gallium nitride-on-silicon interface and associated fabrication process.

2. Description of the Related Art

Gallium nitride (GaN) is a Group III/Group V compound semiconductor material with wide bandgap (3.4 eV), which has optoelectronic, as well as other applications. Like other Group III nitrides, GaN has a low sensitivity to ionizing radiation, and so, is useful in solar cells. GaN is also useful in the fabrication of blue light-emitting diodes (LEDs) and lasers. Unlike previous indirect bandgap devices (e.g., silicon carbide), GaN LEDs are bright enough for daylight applications. GaN devices also have application in high power and high frequency devices, such as power amplifiers.

GaN LEDs are conventionally fabricated using a metalorganic chemical vapor deposition (MOCVD) for deposition on a sapphire substrate. Zinc oxide and silicon carbide (SiC) substrate are also used due to their relatively small lattice constant mismatch. However, these substrates are expensive to make, and their small size also drives fabrication costs. For example, the state-of-the-art sapphire wafer size is relatively small when compared to silicon wafers. The most commonly used substrate for GaN-based devices is sapphire. The low thermal and electrical conductivity constraints associated with sapphire make device fabrication more difficult. For example, all contacts must be made from the top side. This contact configuration complicates contact and package schemes, resulting in a spreading-resistance penalty and increased operating voltages. The poor thermal conductivity of sapphire [0.349 (W/cm-° C.)], as compared with that of Si [1.49 (W/cm-° C.)] or SiC, also prevents efficient dissipation of heat generated by high-current devices, such as laser diodes and high-power transistors, consequently inhibiting device performance.

To minimize costs, it would be desirable to integrate GaN device fabrication into more conventional Si-based IC processes, which has the added cost benefit of using large-sized (Si) wafers. Si substrates are of particular interest because they are less expansive and they permit the integration of GaN-based photonics with well-established Si-based electronics. The cost of a GaN heterojunction field-effect transistor (HFET) for high frequency and high power application could be reduced significantly by replacing the expensive SiC substrates that are conventionally used.

FIG. 1 is a graph depicting the lattice constants of GaN, Si, SiC, AlN and sapphire (prior art). There are two fundamental problems associated with GaN-on-Si device technology. First, there is a lattice mismatch between Si and GaN. The difference in lattice constants between GaN and Si, as shown in the figure, results in a high density of defects from the generation of threading dislocations. This problem is addressed by using a buffer layer of AlN, InGaN, AlGaN, or the like, prior to the growth of GaN. The buffer layer provides a transition region between the GaN and Si.

FIG. 2 is a graph depicting the thermal expansion coefficients (TECs) of GaN, Si, SiC, AlN, and sapphire (prior art). An additional and more serious problem exists with the use of Si, as there is also a thermal mismatch between Si and GaN. GaN-on-sapphire experiences a compressive stress upon cooling. Therefore, film cracking is not as serious of an issue as GaN-on-Si, which is under tensile stress upon cooling, causing the film to crack when the film is cooled down from the high deposition temperature. The thermal expansion coefficient mismatch between GaN and Si is about 54%.

The film cracking problem has been analyzed in depth by various groups, and several methods have been tested and achieve different degrees of success. The methods used to grow crack-free layers can be divided into two groups. The first method uses a modified buffer layer scheme. The second method uses an in-situ silicon nitride masking step. The modified buffer layer schemes include the use of a graded AlGaN buffer layer, AlN interlayers, and AlN/GaN or AlGaN/GaN-based superlattices.

Although the lattice buffer layer may absorb part of the thermal mismatch, the necessity of using temperatures higher than 1000° C. during epi growth and other device fabrication processes may cause wafer deformation. The wafer deformation can be reduced with a very slow rate of heating and cooling during wafer processing, but this adds additional cost to the process, and doesn't completely solve the thermal stress and wafer deformation issues.

It is generally understood that a buffer layer may reduce the magnitude of the tensile growth stress and, therefore, the total accumulated stress. However, from FIG. 2 it can be seen that there is still a significant difference in the TEC of these materials, as compared with GaN. Therefore, thermal stress remains a major contributor to the final film stress.

It would be advantageous if the thermal mismatch problem associated with GaN-on-Si device technology could be practically eliminated by pre-compressing a thermal interface interposed between the GaN and Si layers.

### SUMMARY OF THE INVENTION

The “a” lattice constants of GaN, Si, and sapphire are about 0.319 nanometers (nm), 0.543 nm, and 0.476 nm, respectively. For GaN on Si (111), the relevant comparison is a_{GaN} to a_{Si}/(2^{1/2}) giving a mismatch of about −20.4% at room temperature. For GaN on (0001) oriented sapphire, the relevant comparison is (3/2)^{1/2}×a_{GaN} to aₛₐₚₚₕᵢᵣₑ/2, leading to a mismatch of about +14% at room temperature. Thus, the lattice mismatch between GaN and sapphire is less severe than that between GaN and silicon.

The thermal expansion coefficients for GaN, Si, and sapphire are 4.3e-6 at 300K for a, 3.9e-6 at 300K for c, 2.57e-6 at 300K, and ˜4.0e-6 at 300K for both a and c, respectively, but rises very rapidly with temperature. The thermal expansion mismatch between GaN and Si is more severe than that between GaN and sapphire, as the former system results in GaN films under tensile strain (leading to cracking), and the latter system produces GaN under compressive stress, which causes fewer problems. Therefore, a new structure to release the thermal expansion related stress would be useful for growing GaN on silicon substrates.

The GaN growth temperature is normally 1050° C. or higher. Therefore, when the wafer is cooled down from the growth chamber, the GaN shrinks faster than the silicon substrate, but is partly restrained by the silicon. As a result, a tensile stress is applied to the GaN film that may cause the GaN film to crack. However, if a pre-compressed layer is formed on Si substrates at GaN growth temperatures, the pre-compressed layer reduces the tensile stress as the GaN film is cooled down from growth temperature, and a crack-free GaN film on Si can be made. Film materials such as Al₂O₃, Si1-xGex, InP, GaP, GaAs, AlN, AlGaN, or GaN, may be initially grown at a low temperature. Then, by increasing the growth temperatures, a compressed layer of epitaxial GaN can be formed on a Si substrate.

Accordingly, a method is provided for forming a matching thermal expansion interface between silicon (Si) and gallium nitride (GaN) films. The method provides a (111) Si substrate that is heated to a temperature in a range of about 300 to 800° C., and a first film is formed in compression overlying the Si substrate. The first film material may be InP, SiGe, GaP, GaAs, AlN, AlGaN, an AlN/graded AlGaN (Al₁₋ₓGaₓN (0<x<1)) stack, or a AlN/graded AlGaN/GaN stack. The first film is then nanoscale patterned and a lateral nanoheteroepitaxy overgrowth (LNEO) process is used to grow a first GaN layer. The above-mentioned processes are repeated, forming a second film in compression that is nanoscale patterned, and a second GaN layer is grown using the LNEO process. The first and second GaN layers are formed by heating the Si substrate to a temperature in a range of 1000 to 1200° C.

The first and second films are nanoscale patterned by forming a nanoscaled pattern layer overlying the films. The nanoscaled pattern layer may be either anodized aluminum oxide (AAO) or black polymer. If an AAO nanoscaled pattern layer is used, the material being oxidized is typically AlN, an AlN/graded AlGaN (Al₁₋ₓGaₓN (0<x<1)) stack, an AlN/AlGaN/GaN stack, or Al. The nanoscale pattern is formed by etching exposed areas of the film. Subsequent to etching, the nanoscaled pattern layer is removed.

Additional details of the above-mentioned method and a GaN-on-Si thermal expansion interface are provided below.

### BRIEF DESCRIPTION OF THE DRAWINGS

FIG. 1 is a graph depicting the lattice constants of GaN, Si, SiC, AlN and sapphire (prior art).

FIG. 2 is a graph depicting the thermal expansion coefficients (TECs) of GaN, Si, SiC, AlN, and sapphire (prior art).

FIG. 3 is a partial cross-sectional view of a silicon (Si)-to-gallium nitride (GaN) thermal expansion interface.

FIG. 4 is a partial cross-section view of a first variation of the Si-on-GaN interface of FIG. 3.

FIG. 5 is a partial cross-section view of a second variation of the Si-on-GaN interface of FIG. 3.

Table 1 and FIG. 6 depict the lattice and thermal expansion coefficient data, respectively, of GaN on Si related materials.

FIG. 7 through 10 depicts fabrication steps in the completion of the interface of FIG. 3.

FIG. 11 is a flowchart illustrating a method for forming a matching thermal expansion interface between Si and GaN films.

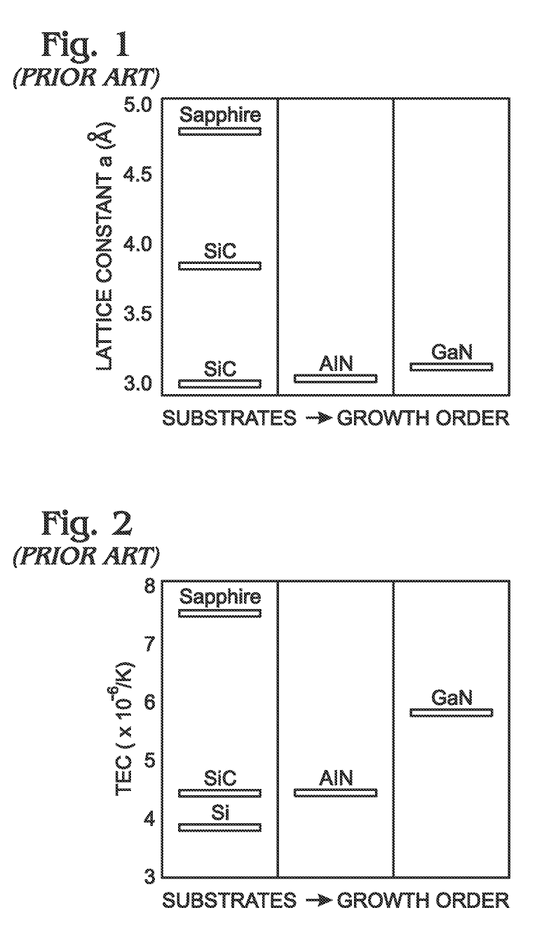

### DETAILED DESCRIPTION

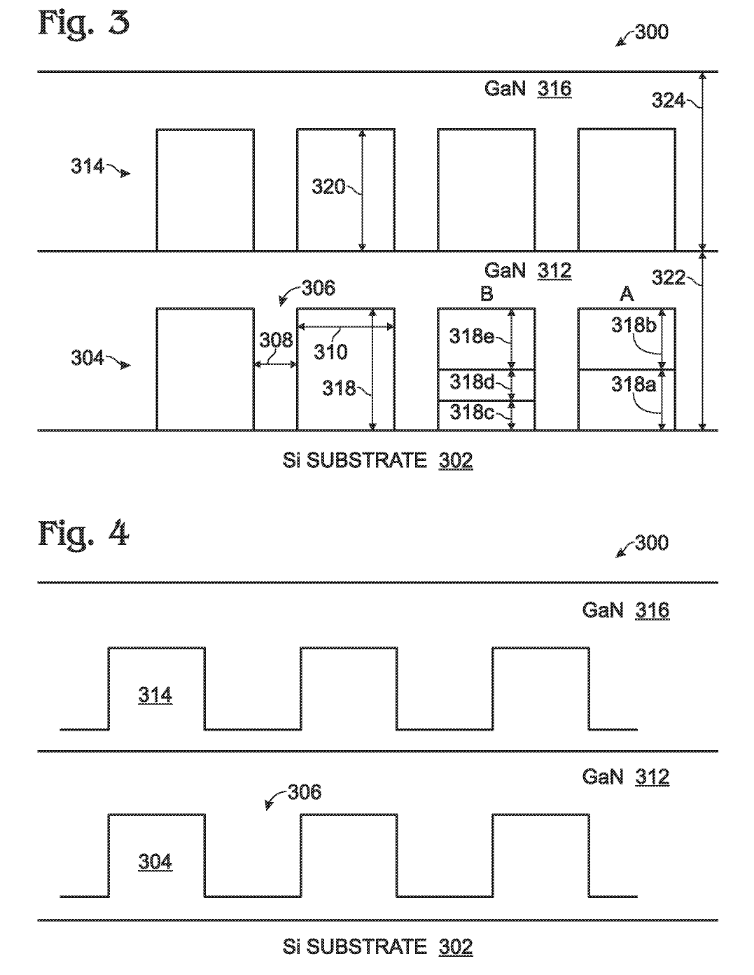

FIG. 3 is a partial cross-sectional view of a silicon (Si)-to-gallium nitride (GaN) thermal expansion interface. The interface 300 comprises a (111) Si substrate 302. A nanoscale patterned first film 304 is formed in compression over the Si substrate 302. The first film 304 material may be InP, SiGe, GaP, GaAs, AlN, AlGaN, an AlN/graded AlGaN (Al₁₋ₓGaₓN (0<x<1)) stack, or a AlN/graded AlGaN/GaN stack. The pattern includes openings 306 having a diameter 308 in a range between 5 and 100 nanometers (nm), and a distance 310 between openings in a range between 100 nm and 2 micrometers. A first GaN layer 312 is formed in etched regions (e.g., the openings 306) of first film and covering the first film 304. A nanoscale patterned second film 314 is formed in compression over the first GaN layer 312. The second film 314 material is one of the above-mentioned first film 304 materials. Likewise, the second film 314 nanoscale patterning is a described above for the first film. A second GaN layer 316 is formed in etched regions of the second film and covering the second film 314.

Generally, the first film 304 and second film 314 have thicknesses 318 and 320, respectively, in the range of about 5 to 500 nanometers (nm). For example, if the first and second films 304/314 are an AlN film, the thicknesses 318/320 are in the range of about 5 to 500 nm. In another aspect (see detail A), the first and second films 304/314 are an AlN/graded AlGaN stack, where the AlN film has a thickness 318a in the range of about 5 to 500 nm and the AlGaN has a thickness 318b in the range of about 10 to 500 nm. Although not specifically shown, the AlN and AlGaN thicknesses are in same ranges for the second film 314.

In one aspect (see detail B), the first and second films 304/314 are an AlN/AlGaN/GaN stack, where the AlN film has a thickness 318c in a range of about 5 to 500 nm, the AlGaN is graded and has a thickness 318d in a range of about 5 to 500 nm, and the GaN 318e has a thickness in a range of about 0.2 to 1 micrometer (μm). Although not specifically shown, the AlN, AlGaN, and GaN thicknesses are in same ranges for the second film 314. The first GaN layer 312 has a thickness 322 in a range of 0.3 to 1 micrometers, and the second GaN layer 316 has a thickness 324 in a range of 1 to 4 micrometers.

In one aspect, as shown in FIG. 3, the nanoscale patterned first and second film openings 306 are patterned to the depth of the Si substrate 302 and first GaN layer 312, respectively. That is, the openings 306 extend all the way through the first and second films 304/314 to expose the underlying films.

FIG. 4 is a partial cross-section view of a first variation of the Si-on-GaN interface of FIG. 3. In this aspect, the nanoscale patterned first and second film openings 306 do not extend through the films 304/314 to the depth of the Si substrate 302 and first GaN layer 312, respectively.

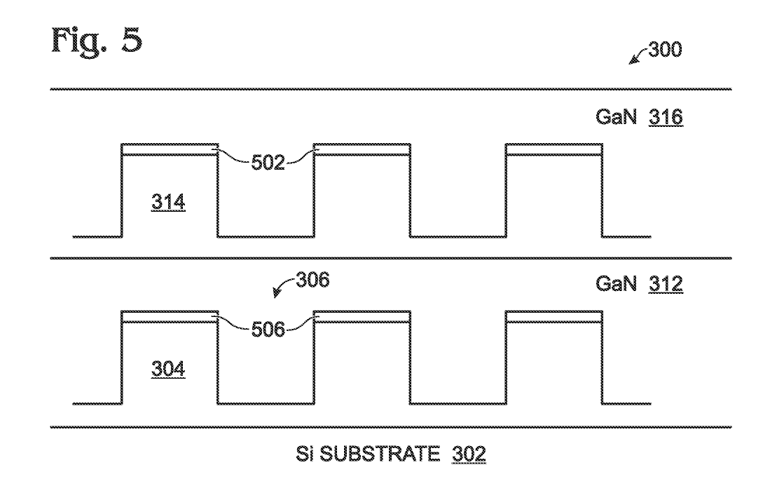

FIG. 5 is a partial cross-section view of a second variation of the Si-on-GaN interface of FIG. 3. In this aspect, a first lattice mismatch film 500 overlies unpatterned (unetched) regions of the first film 304. A second lattice mismatch film 502 overlies unpatterned regions of the second film 314. The first and second lattice mismatch films 500 and 502 are an oxide or nitride material such as SiO₂, ZrO₂, HfO₂, or SiN. As shown, the lattice mismatch films 500 and 502 are used in an interface variation where the openings 306 though the first and second films 304/314 do not extend all the way through to the underlying layers (as in FIG. 4). However, even though it is not specifically shown, it should be understood that lattice mismatch films may be used in interface variations where the first and second film openings do extend through to the underlying layers, as in FIG. 3.

### Functional Description

A pre-compressed layer is formed on Si substrates at GaN growth temperatures. The pre-compressed layer reduces the tensile stress as the GaN film is cooled down from growth temperature, and a crack-free GaN film on Si can be made. Materials such as Al₂O₃, Si₁₋ₓGex, InP, GaP, GaAs, AlN, AlGaN, and GaN may be initially grown at low temperature, with a subsequent increase to higher temperatures to form a compressed layer. The compressed layer acts as an interface between an epi GaN film and a Si substrate.

When a coating is cooled after deposition, and its thermal expansion coefficient, α_{c}, is larger than that of the substrate, αₛ, (as in the case of GaN on Si), the coating is under tensile strain. As a result, the uncracked film-substrate composite bends, having a radius of curvature, ρ, as

1/ρ=(αₛ−α_{c})(T_{f}−T_{g})/[h/2+2(E_{c}*I_{c}+Eₛ*Iₛ)/h(1/E_{c}*t_{c}+1/Eₛ*tₛ)] (1)

where T_{f} is the final temperature after cooling; T_{g} is the growth temperature; t_{c} and tₛ are the individual coating and substrate thicknesses; h is the total thickness (h=t_{c}+tₛ); I is the moment of inertia, I=t³/12; and E* is the effective modulus of elasticity. These conditions apply for wide layers and plane strain conditions E*=E/(12−v²), where E is the Young's modulus of elasticity and v is the Poisson's ratio.

From formula (1), the quantity [h/2+2(E_{c}*I_{c}+Eₛ*Iₛ)/h(1/E_{c}*t_{c}+1/Eₛ*tₛ)] is called A. A decreases with an increase in the thickness of the coating materials. But if tc<<ts, the coating thickness effect for A can be ignored. The formula (1) changes to

1/ρ=(αₛ−α_{c})(T_{f}−T_{g})/A (2)

Since the coating is thin (t_{c}<0.1tₛ), the predicted inplane normal stress in the uncracked coating is uniform and is given by

σₚ=1/ρ[2/ht_{c}(E_{c}*I_{c}+Eₛ*Iₛ)+E_{c}*t_{c}/2] (3)

The quantity [2/ht_{c}(E_{c}*I_{c}+Eₛ*Iₛ)+E_{c}*t_{c}/2] is called B. B increases with an increase in the thickness of coating materials. The formula (3) changes to

σₚ=B(αₛ−α_{c})(T_{f}−T_{g})/A (4)

Let B/A=R, which increases with an increase in the thickness of the coating materials. The formula (4) can be written as

σₚ=R(αₛ−α_{c})(T_{f}−T_{g}) (5)

From formula (5), when the thermal expansion coefficient of the coating material is larger than that of the substrate and is deposited at higher temperatures, the coating materials are under tensile stress (σₚ>0) after cooling down. In contrast, when the thermal expansion coefficient of the coating material is larger than that of the substrate and deposited at lower temperatures, the coating materials is under compressive stress (σₚ<0) when heated to higher temperatures.

Therefore, if materials are grown with a higher thermal expansion coefficient on Si substrates at lower temperatures, the coated materials will be under compression when the wafer is heated to higher temperature, such as the temperatures required for GaN growth. During the wafer cooling down process, the compressed layer reduces the tensile stress of the overlying GaN films, and a crack-free GaN film on a Si substrate is formed.

Table 1 and FIG. 6 depict the lattice and thermal expansion coefficient data, respectively, of GaN on Si related materials. From this data, it can be seen that Al₂O₃, Si₁₋ₓGex, InP, GaP, GaAs, AlN, AlGaN, and GaN, etc., may be used to make a pre-compressed layer on Si substrates. Ge, InP, GaP, and GaAs, etc., can be grown at lower temperatures. AlN has been successfully grown on Si at room temperature. Al₂O₃ can be coated on Si substrates by AAO processes, GaN can also be grown below 700° C., and the temperature increased for epitaxial (epi) GaN growth. Therefore, there are several materials that can be initially grown on Si at low temperatures, with an increase to higher temperatures, to form a compressed layer for epi GaN deposition.

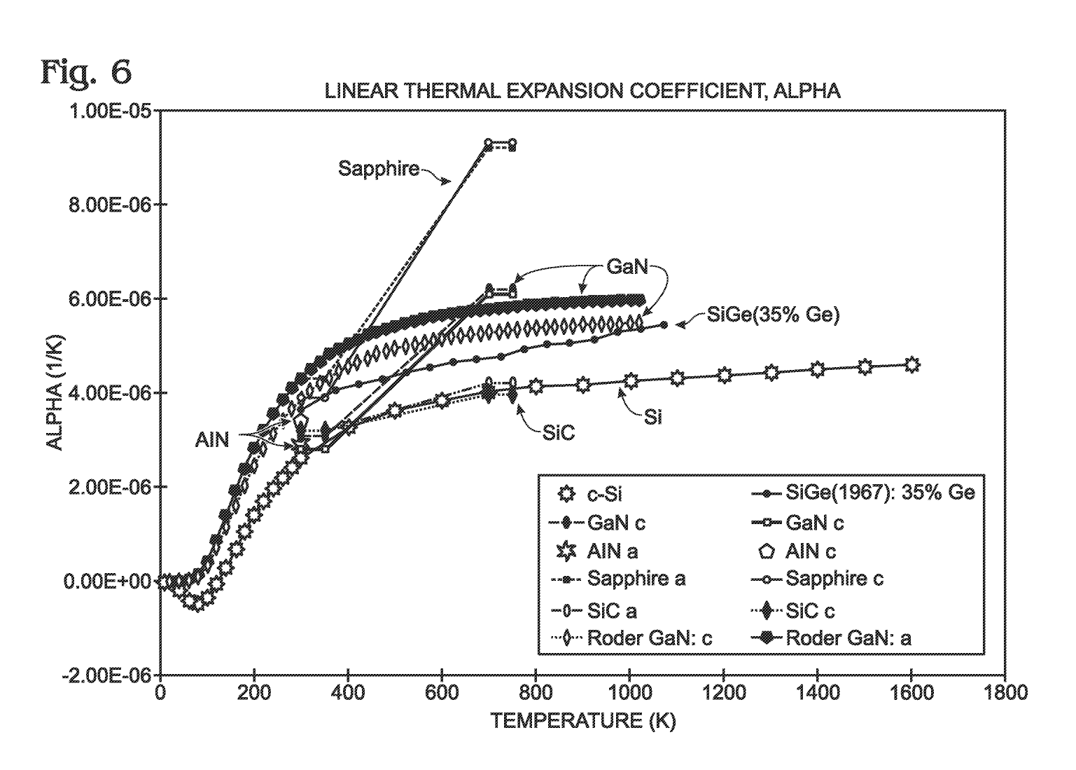

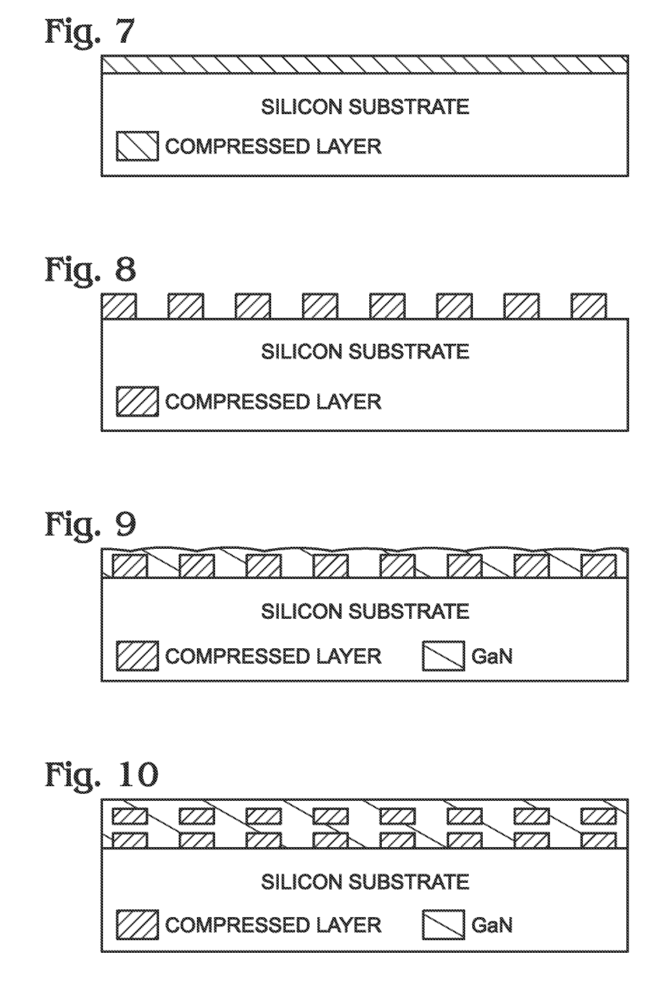

FIG. 7 through 10 depicts fabrication steps in the completion of the interface of FIG. 3. The starting wafer is a <111> oriented silicon substrate. In one aspect, the silicon substrate is cleaned and a 5 to 500 nm thick layer of first film (compressed layer) is deposited, see FIG. 7. One of the following first film materials may be deposited: InP, SiGe, GaP, GaAs, AlN, AlGaN, or GaN, at low temperatures (temperature range from 300-800° C.). Optionally, the silicon substrate may be cleaned using in-situ hydrogen treatments of the Si substrate, and one of the following first film materials is deposited: AlN, or AlN/graded AlGaN, or AlN/graded AlGaN/GaN.

In FIG. 8 the first film is nanoscale patterned and then either partially etched or fully etched. As shown, the first film is fully etched. Alternately as shown in FIG. 4, the first film may be partially etched.

In FIG. 9, lateral nanoheteroepitaxy overgrowth GaN is formed on the first film at higher temperature of about 1000-1200° C.

In FIG. 10, the steps of depositing a compressed layer, nanoscale patterning the compressed layer, and deposited a GaN layer are repeated. If the surface of the LNEO GaN is not sufficiently flat, an optional chemical mechanical polishing (CMP) may be performed. After the CMP, an additional GaN layer may be grown to form very smooth GaN film.

TABLE 1
Crystal structure, lattice parameters, and thermal
expansion coefficient of selected semiconductor materials

| | | Lattice | Thermal | | | |
|---|---|---|---|---|---|---|
| | Crystal | parameter | Expansion Coeff. | Dielectric | Refractive | Bandgap |
| Materials | Structure | (Å) | (×10⁶/° C.)@25° C. | constant (ε) | Index (n) | (eV)@25° C. |
| GaN | W | a = 3.190 (1) | a: 4.3 (7) | 9.5 | | 3.34 (1) |
| | | c = 5.189 (1) | c: 3.9 (7) | | | |
| GaN | Z | a = 4.52 | | | | 3.2-3.3 |
| AlN | W | a = 3.111 (1) | 2.0 (5.3) | 8.5-9 | | 6.02 (1) |
| | | c = 4.978 (1) | 3.0 (4.2) | | | |
| AlN | Z | a = 4.38 | | | | 5.11 |
| Al₂O₃ | R | a = 4.758 | 4.0 (9) | 4.5-8.4 | 1.76 (4) | >8 (4) |
| | | c = 12.991 | 7.5, 8.3(4) | (1) | | |
| | | | | 8.6-10.6 | | |
| | | | | (4) | | |
| Si | D | a = 5.431 | 2.57 (8) | 11.8 (1) | 3.49 (1) | 1.107 (1) |
| GaAs | Z | a = 5.653 (1) | 4.68 (1), 3.59 (6), | 13.2 (1) | | 1.4 |
| | | | 5.4 (1) | | | |
| 6H—SiC | W | a = 3.076 (1) | 3.3 (4.2) | 10 | 2.654 (1) | 2.9 |
| | | c = 5.048 (1) | (4.7) | | | |
| 3c-SiC | Z | a = 4.348 (1) | 2.7 (2.9) | 9.7 | 2.697 (1) | 2.3 (1) |
| InP | Z | a = 5.869 (1) | 4.6 (1) | 12.4 (1) | 3.1 (1) | 1.27 (1) |
| InN | W | a = 3.533 (1) | 4 | | | 2.0 (1) |
| | | c = 5.693 (1) | | | | 1.89 |
| InN | Z | a = 4.98 | | | | 2.2 |
| GaP | Z | a = 5.451 (1) | 5.3 (1) | 11.1 (1) | 3.2 (1) | 2.24 (1) |
| MgO | C | a = 4.216 (1) | 10.5, 13.5 (4) | 9.65 (4) | 1.74 (4) | >7.8 (4) |
| ZnO | W | a = 3.25 (1) | 2.9 | | | 3.2 (1) |
| | | c = 5.207 (1) | 4.75 | | | |

Anodized aluminum oxide (AAO) can be used as a nanoscale porous alumina template hardmask to form nanoscale patterns in Si (111), AlN, graded AlₓGa₁₋ₓN (1≧x≧0), GaN, and other compressed layer (first and second film) materials, as part of the process of forming a high quality thick GaN overgrowth. For example, high quality aluminum films can be deposited on a silicon substrate using E-beam evaporation, with a film thickness of 0.5 to 1.5 μm. Both oxalic and sulfuric acid may be used in the anodization process. In a first step, the aluminum coated wafers are immersed in acid solution at 0° C. for 5 to 10 minutes for an anodization treatment. Then, the alumina formed in the first anodic step is removed by immersion in a mixture of H₃PO₄ (4-16 wt %) and H₂Cr₂O₄ (2-10 wt %) for 10 to 20 minutes. After cleaning the wafer surface, the aluminum film is exposed to a second anodic treatment, the same as the first step described above. Finally, the porous alumina template is further treated in 2-8 wt % H₃PO₄ aqueous solution for 15 to 90 minutes to increase the nanoscale features.

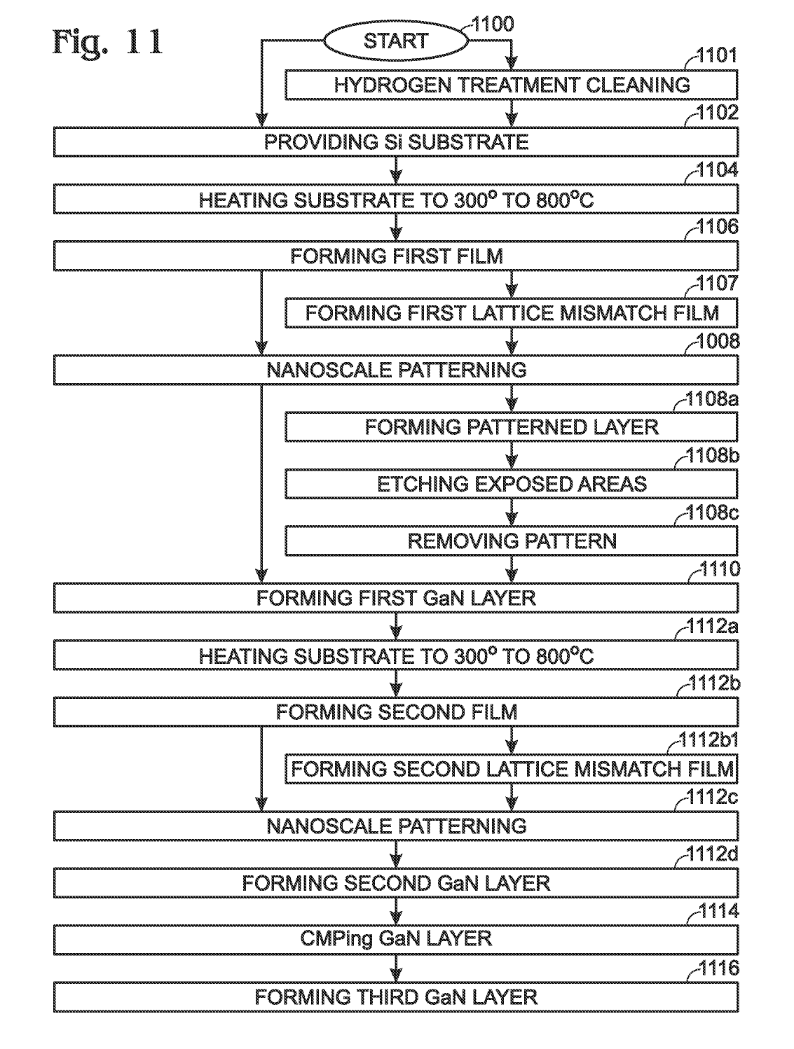

FIG. 11 is a flowchart illustrating a method for forming a matching thermal expansion interface between Si and GaN films. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1100.

Step 1102 provides a (111) Si substrate. Step 1104 heats the Si substrate to a temperature in the range of about 300 to 800° C. Step 1106 forms a first film in compression overlying the Si substrate, where the first film material may be one of the following materials: InP, SiGe, GaP, GaAs, AlN, AlGaN, an AlN/graded AlGaN (Al₁₋ₓGaₓN (0<x<1)) stack, or a AlN/graded AlGaN/GaN stack. In one aspect, prior to forming the first film overlying the Si substrate, Step 1101 cleans the Si substrate top surface using an in-situ hydrogen treatment. Step 1108 nanoscale patterns the first film. Nanoscale patterning the first film includes forming a pattern with openings having a diameter in the range between 5 and 100 nm, and a distance between openings in a range between 100 nm and 2 micrometers.

Step 1110 uses a lateral nanoheteroepitaxy overgrowth (LNEO) process to grow a first GaN layer. Step 1112 repeats the above-mentioned Steps (Step 1104 through 1110). That is, Step 1112a heats the Si substrate to a temperature in the range of 300 to 800° C. Step 1112b forms a second film in compression. Step 1112c nanoscale patterns the second film. The nanoscale patterning dimensions described above with respect to Step 1108 also apply to the patterning of the second film. Step 1112d grows a second GaN layer using the LNEO process.

Generally, the first and second films formed in Step 1106 and 1112b have a thickness in a range of about 5 to 500 nanometers (nm), as is the case if the films are AlN. If the first and second films are an AlN/graded AlGaN stack, then the AlN film has a thickness in the range of about 5 to 500 nm and the AlGaN has a thickness in the range of about 10 to 500 nm. If the first and second films are an AlN/AlGaN/GaN stack, the AlN film has a thickness in the range of about 5 to 500 nm, the AlGaN is graded and has a thickness in the range of about 5 to 500 nm, and the GaN has a thickness in the range of about 0.3 to 1 micrometer (μm).

In one aspect, growing the first and second GaN layers in Step 1110 and 1112d, respectively, includes heating the Si substrate to a temperature in a range of 1000 to 1200° C. Typically, the first GaN layer has a thickness in the range of 0.3 to 1 micrometers, and the second GaN layer has a thickness in the range of 1 to 4 micrometers

In one aspect, growing the second GaN layer in Step 1112d includes forming a GaN top surface. Then, Step 1114 performs a chemical mechanical polishing (CMP) on the GaN top surface, and Step 1116 grows a third GaN layer using the LNEO process.

In another aspect, nanoscale patterning the first film in Step 1108 includes substeps. Step 1108a forms a nanoscaled pattern layer overlying the first film from either an anodized aluminum oxide (AAO) or black polymer material. Step 1108b etches exposed areas of the first film forming the nanoscale pattern. Subsequent to etching the first film, Step 1108c removes the nanoscaled pattern layer. Although not specifically shown, the same substeps would apply to nanoscale patterning the second film in Step 1112c. If the nanoscaled pattern layer is AAO, then a film material such as AlN, an AlN/graded AlGaN (Al₁₋ₓGaₓN (0<x<1)) stack, an AlN/AlGaN/GaN stack, or Al is deposited and oxidized.

In one aspect, forming the first film in Step 1106 includes forming a first film with a first thickness, and nanoscale patterning the first film in Step 1108 includes partially etching nanoscale features in the first film to a depth less than the first thickness. Alternately, Step 1108 fully etches nanoscale features through the first film, exposing underlying areas of the Si substrate. The alternatives of partially or fully etching the first film also apply to nanoscale patterning the second film in Step 1112c.

In another aspect, Step 1107 forms first lattice mismatch films overlying the first film and Step 1112b1 forms a second lattice mismatch film overlying the second film. The lattice mismatch films can be an oxide or nitride material such as SiO₂, ZrO₂, HfO₂, or SiN. Then, nanoscale patterning the first film in Step 1108 includes leaving the lattice mismatch film overlying unpatterned regions of the first film. Likewise, nanoscale patterning the second film in Step 1112c includes leaving the lattice mismatch film overlying unpatterned regions of the second film. Growing the first GaN layer in Step 1110 includes selectively growing GaN from regions not covered by the lattice mismatch film. Likewise, growing the second GaN layer in Step 1112d includes selectively growing GaN from regions not covered by the lattice mismatch film.

A GaN-on-Si thermal expansion interface and associated fabrication process have been provided. Some examples and materials, dimensions, and process steps have been given to illustrate the invention. However, the invention is not limited to merely these examples. Other variations and embodiments of the invention will occur to those skilled in the art.

We claim:

1. A method for forming a matching thermal expansion interface between silicon (Si) and gallium nitride (GaN) films, the method comprising:
providing a (111) Si substrate;
heating the Si substrate to a temperature in a range of about 300 to 800° C.;
forming a first film in compression overlying the Si substrate, where the first film material is selected from a group consisting of InP, SiGe, GaP, GaAs, AlN, AlGaN, an AlN/graded AlGaN (Al₁₋ₓGaₓN (0<x<1)) stack, and a AlN/graded AlGaN/GaN stack;
nanoscale patterning the first film;
using a lateral nanoheteroepitaxy overgrowth (LNEO) process, growing a first GaN layer; and,
repeating the above-mentioned processes, forming a second film in compression, nanoscale patterning the second film, and growing a second GaN layer using the LNEO process.

2. The method of claim 1 wherein forming the first and second films includes forming a film having a thickness in a range of about 5 to 500 nanometers (nm).

3. The method of claim 1 wherein forming the first and second films includes forming an AlN film having a thickness in a range of about 5 to 500 nanometers (nm).

4. The method of claim 1 wherein forming the first and second films includes forming an AlN/graded AlGaN stack, where the AlN film has a thickness in a range of about 5 to 500 nm and the AlGaN has a thickness in a range of about 10 to 500 nm.

5. The method of claim 1 wherein forming the first and second films includes forming an AlN/AlGaN/GaN stack, where the AlN film has a thickness in a range of about 5 to 500 nm, the AlGaN is graded and has a thickness in a range of about 5 to 500 nm, and the GaN has a thickness in a range of about 0.3 to 1 micrometer (μm).

6. The method of claim 1 wherein growing the second GaN layer includes forming a GaN top surface; and,
the method further comprising:
performing a chemical mechanical polishing (CMP) on the GaN top surface; and,
growing a third GaN layer using the LNEO process.

7. The method of claim 1 further comprising:
prior to forming the first film overlying the Si substrate, cleaning a Si substrate top surface using an in-situ hydrogen treatment.

8. The method of claim 1 wherein growing the first and second GaN layers includes heating the Si substrate to a temperature in a range of 1000 to 1200° C.

9. The method of claim 1 wherein growing the first GaN layer includes growing a GaN layer having a thickness in a range of 0.3 to 1 micrometers; and,
wherein growing the second GaN layer includes growing a GaN layer having a thickness in a range of 1 to 4 micrometers

10. The method of claim 1 wherein nanoscale patterning the first film includes:
forming a nanoscaled pattern layer overlying the first film selected from a group consisting of anodized aluminum oxide (AAO) and black polymer;
etching exposed areas of the first film forming the nanoscale pattern; and,
subsequent to etching the first film, removing the nanoscaled pattern layer.

11. The method of claim 10 wherein forming the nanoscaled pattern layer of AAO includes using a film material selected from a group consisting of AlN, an AlN/graded AlGaN (Al₁₋ₓGaₓN (0<x<1)) stack, an AlN/AlGaN/GaN stack, and Al.

12. The method of claim 1 wherein forming the first film includes forming a first film with a first thickness; and,
wherein nanoscale patterning the first film includes partially etching nanoscale features in the first film to a depth less than the first thickness.

13. The method of claim 1 wherein nanoscale patterning the first film includes fully etching nanoscale features through the first film, exposing underlying areas of the Si substrate.

14. The method of claim 1 further comprising:
forming first and second lattice mismatch films overlying the first and second films, respectively, the lattice mismatch films being selected from a group consisting of SiO₂, ZrO₂, HfO₂, and SiN;
wherein nanoscale patterning the first and second films includes leaving the lattice mismatch film overlying unpatterned regions of film; and,
wherein growing the first and second GaN layers includes selectively growing GaN from regions not covered by the lattice mismatch film.

15. The method of claim 1 wherein nanoscale patterning the first film includes forming a pattern with openings having a diameter in a range between 5 and 100 nanometers (nm), and a distance between openings in a range between 100 nm and 2 micrometers.

16. A silicon (Si)-to-gallium nitride (GaN) thermal expansion interface, the interface comprising:
a (111) Si substrate;
a nanoscale patterned first film formed in compression over the Si substrate, the first film material selected from a first group consisting of InP, SiGe, GaP, GaAs, AlN, AlGaN, an AlN/graded AlGaN (Al₁₋ₓGaₓN (0<x<1)) stack, and a AlN/graded AlGaN/GaN stack, wherein the pattern includes openings having a diameter in a range between 5 and 100 nanometers (nm), and a distance between openings in a range between 100 nm and 2 micrometers (μm);
a first GaN layer formed in etched regions of first film and covering the first film;
a nanoscale patterned second film formed in compression over the first GaN layer, the second film material selected from the first group of materials; and,
a second GaN layer formed in etched regions of the second film and covering the second film.

17. The interface of claim 16 further comprising:
a first lattice mismatch film overlying unpatterned regions of the first film;
a second lattice mismatch film overlying unpatterned regions of the second film; and,
wherein the first and second lattice mismatch films are a material selected from a group consisting of SiO₂, ZrO₂, HfO₂, and SiN.

18. The interface of claim 16 wherein the first and second films are an AlN film having a thickness in a range of about 5 to 500 nm.

19. The interface of claim 16 wherein the first and second films are an AlN/graded AlGaN stack, where the AlN film has a thickness in a range of about 5 to 500 nm and the AlGaN has a thickness in a range of about 10 to 500 nm.

20. The interface of claim 16 wherein the first and second films are an AlN/AlGaN/GaN stack, where the AlN film has a thickness in a range of about 5 to 500 nm, the AlGaN is graded and has a thickness in a range of about 5 to 500 nm, and the GaN has a thickness in a range of about 0.2 to 1 μm.

21. The interface of claim 16 wherein the first GaN layer has a thickness in a range of 0.3 to 1 micrometers; and,
wherein the second GaN layer has a thickness in a range of 1 to 4 micrometers.

22. The interface of claim 16 wherein the nanoscale patterned first and second film openings are patterned to the depth of the Si substrate and first GaN layer, respectively.

23. The interface of claim 16 wherein the nanoscale patterned first and second film openings do not extend through the films to the depth of the Si substrate and first GaN layer, respectively.
